(19) United States
(12) Patent Application Publication
(10) Pub. No.: US 2010/0067290 A1
(43) Pub. Date: Mar. 18, 2010

(54) Method of programming of phase-change memory and associated devices and materials

(76) Inventor: Semyon D. Savransky, Newark, CA (US)

Correspondence Address: Semyon D. Savransky, 6015 Pepper Tree Court, Newark, CA, 94560, US

(21) Appl. No.: 12/584,821

(22) Filed: Sep. 14, 2009

Related U.S. Application Data
(60) Provisional application No. 61/096,864, filed on Sep. 15, 2008.

(51) Int. Cl. G11C 11/00; G11C 7/00

(52) U.S. Cl. 365/163; 365/189.16; 365/148

(57) ABSTRACT

A method of programming a phase-change memory (PCM) device to the high resistance reset state by means of pressure-induced amorphization. A train of few short pulses is applied to the PCM device produces high pressure on phase-change alloy (PCA). PCM device contains a PCA with easily deformed atomic structure by external pressure and materials mechanically contacted PCA. These materials have lower coefficients of thermal expansion and compressibility as well as higher coefficient of hardness than the corresponding coefficients of the PCA.

### CROSS REFERENCE TO RELATED APPLICATIONS

Benefit of U.S. Provisional Application No. 61,096,864 (EFS ID: 3939157) filed Sep. 15, 2008, is claimed. The application is incorporated herein by reference.

### REFERENCE TO A SEQUENCE LISTING, A TABLE, OR A COMPUTER PROGRAM LISTING COMPACT DISK APPENDIX

Not Applicable.

### REFERENCE REGARDING FEDERAL SPONSORSHIP

Not Applicable.

### STATEMENT REGARDING FEDERALLY SPONSORED RESEARCH OR DEVELOPMENT

Not Applicable.

### BACKGROUND OF THE INVENTION

1. Field of the Invention

Electrical memory based on reversible transition of active material between various states, for example phase-change memory (PCM). The invention relates to an electrical memory and, in particular, to programming methods for PCM into reset states.

2. Description of Related Art

Phase-change memory (PCM) stores data in a phase-change alloy (PCA), the electric resistance of which varies upon a phase transition between two or more states. Phase-change memory (PCM) can be read and programmed very quickly and do not require power to maintain their state. PCM has many of the advantages of both volatile memories such as dynamic random access memories and non-volatile memories such as Flash.

The known PCM works due to reversible transition between crystalline and amorphous phases in atomic structure of a phase-change alloy (PCA). The resistance of the PCA in the reset (amorphous) state is greater than the resistance of the PCA in the set (crystalline) state. These set and reset states can be assigned for different logic values, e.g. 1 and 0.

The transition from the amorphous to the crystalline phase occurs due to crystallization initiated by a long electrical pulse with a moderate electrical current that heats up PCA to crystallization temperature Tx (so called set pulse).

The transition from the crystalline to amorphous phase in known methods of PCM programming occurs due to melting initiated by a short electrical pulse with a high electrical current that heats up PCA above melting temperature Tm and fast PCA cooling (so called reset pulse).

The melting point Tm is higher than crystallization temperature Tx for all known PCA, therefore an amplitude of the reset pulse is higher than an amplitude of the set pulse.

The electric pulses or pulse trains produce Joule heating of active PCA volume in all prior art methods and embodiments of PCM programming methods. This current heats up active PCA volume to or above crystallization temperature Tx for the set state and to or above melting temperature Tm for the reset state due to the Joule effect.

The PCA may change back and forth between a crystalline state and an amorphous state during a programming pulse when the current flows through a PCM. Because Tm is higher than Tx the reset current is larger than set current. High reset current is the main disadvantage of PCM to compare with other resistive memories.

As an example, a PCA may be heated to its melting point by applying a relatively high current (e.g., 3 mA) pulse to the PCA for a relatively short duration of time (e.g., 10 ns). The PCA may then be rapidly cooled, that changes the PCA to a highly resistive, amorphous state, named as reset state. When PCA in the reset state is heated above its crystallizing temperature by applying a relatively low current pulse (e.g., 500 uA) for relatively long time (e.g., lus) it changes to a lower resistive, crystalline state, named as set state.

It is desirable to spend small energy during PCM programming.

There have been few attempts to reduce reset current by choosing various PCA with small Tm, but such PCA do not satisfy other requirements of a non-volatile memory.

There have been several attempts to reduce reset current by decreasing active amorphous PCA volume in PCM due to scaling of area between PCM electrode and PCA. This approach requires expensive photo-lithography or other methods to make characteristic device features as small as 32 nanometers.

There have been few attempts to reduce reset current by designing PCM with high thermal efficiency, but the best achieved efficiency of PCM is still less than 10 percent.

There have been few attempts to improve PCM by special programming techniques which we describe in details.

Lai and Lowrey, as reported in the paper “OUM-A 180 nm nonvolatile memory cell element technology for stand alone and embedded applications” published in Electron Devices Meeting, 2001. IEDM Technical Digest, 2-5 December 2001 p. 36.5.1-36.5.4, used long (e.g., 500 ns) pulse to achieve a set state of phase change memory. Lai and Lowrey used short (e.g., 100 ns) pulse with high amplitude to melt PCA and then quench it in the reset state. Both pulses are shown in FIG. 1A. Advantage of such reset pulse is simplicity of pulse generating circuit. Disadvantage of such reset pulse is that some of cells in big array can be overheated because of difference in melting temperatures Tm between different PCM cells. This causes low endurance of such PCM cells.

The following sections give comprehensive review of reset pulses proposed for PCM in the prior art that reflects improvements of Lai—Lowrey programming methods.

During reset pulse active volume of PCA should be obtained in mostly the solid amorphous state usually from previously mostly crystalline state. All kinds of reset pulses described in this section are based on vitrification of the melt into active amorphous PCA volume.

Savransky proposed reset pulse with annealing portion (FIG. 1B) to decrease drift in PCA in white paper “Some Peculiarities of Reset Process and Reliability of Chalcogenide Phase-Change Non-Volatile Memory” (August 2005) published at the WWW, see http://www.TRIZExperts.net.

Phillipp et. al., proposed in US Patent Application 2009/0003035 “Conditioning Operations for Memory Cells” (January 2009) to use few successive square or trapezoidal reset pulses (FIG. 1C) with the same amplitude to condition a memory cell. Each of such pulses melts active material in a PCM cell. Such reset pulses train is longer than a single reset pulse, heats up the cell above melting point, and leads to smaller endurance of PCM.

Phillipp et. al., proposed in U.S. Pat. No. 7,577,023 “Memory Including Write Circuit For Providing Multiple Reset Pulses” (August 2009) to use few square reset pulses with decreasing amplitude to PCM cells with various critical dimension in array (FIG. 1D). At least the first pulse melts active material in a PCM cell. The second and following reset pulses with amplitude smaller than the amplitude of the first reset pulse can decrease the resistance of a PCM programmed to reset state by the first reset pulse, therefore decrease the read margin. The amplitude of the first reset pulse can be too high for the some PCM cells that can be programmed by the second and following reset pulses, therefore the first pulse reduces endurance of such PCM cells.

Ming Hsiu Lee and Chou Chen proposed in U.S. Pat. No. 7,272,037 “Method for programming a multilevel phase-change memory device” (September 2007) different free shape pulses for reset state with variable threshold switching voltage. Each of their pulses melts PCA and then PCA cools down in high resistive state.

Jun-Soo Bae et. al., proposed US Patent Application 2009/0073754 (March 2009) reset pulses with rising time longer than failing time for MLC programming of PCM. Each of such pulses melts active material in a PCM cell, and, hence, uses high current for programming.

High programming reset current limits usability of phase-change memory for several applications in which a battery supplies energy for a PCM.

What is needed in the art is a method of programming of the phase-change memory (PCM) into high resistance amorphous reset state with small current. A phase-change alloy (PCA) and a memory cells programmable with small programming current are also desirable.

### BRIEF DESCRIPTION OF THE DRAWINGS

The invention is illustrated by way of example and not by way of limitation in the figures of the accompanying drawings in which like references indicate similar elements. It should be noted that references to “an” embodiment in this disclosure are not necessarily to the same embodiment, and they mean at least one.

FIG. 1A shows pulses for programming a phase-change memory used by Lai and Lowrey. The amplitudes and durations of reset and set pulses are shown for the comparison; Tm and Tx are melting and crystallization temperatures that are achieved during the reset and set pulses.

FIG. 1B shows reset pulse with annealing for drift-free programming a phase-change memory used by Savransky.

FIG. 1C shows square reset pulses with the same amplitude proposed by Phillipp et. al.

FIG. 1D shows few successive square reset pulses proposed by Phillipp et. al. with the same or decreasing amplitude where the lowest amplitude of a pulse brings PCA above the melting point Tm.

FIG. 2 shows a generic phase-change memory device.

FIG. 3A illustrates a sequence of rectangular programming pulses with the same amplitude and the same duration included in a reset train, according to an embodiment of the invention.

FIG. 3B illustrates a sequence of rectangular programming pulses with the same amplitude and different durations included in a reset train, according to an embodiment of the invention. The levels of reset and set currents are shown for the comparison.

FIG. 4 illustrates a sequence of triangular programming pulses included in a reset train, according to an embodiment of the invention.

FIGS. 5A and 5B illustrate a sequence of rectangular programming pulses with non-equal amplitudes included in a reset train, according to an embodiment of the invention. The highest amplitude pulse cannot melt PCA.

FIG. 6 illustrates a plot of PCM cell resistance versus number of equal amplitude pulses in a reset train. The amplitude of each pulse is not enough to melt PCA.

FIG. 7 shows a generic phase-change memory device according to an embodiment of the invention.

FIG. 8 shows an example of PCM array with write circuit and other interface devices.

### DETAILED DESCRIPTION

The present invention explores a new way to obtain the reset state in phase-change memory (PCM) by means of pressure-induced amorphization (sometimes called as stress- or mechanical-induced amorphization), a new construction of PCM device and a new PCA that increase efficiency of pressure-induced amorphization.

According to an embodiment of the invention, the programming a phase-change memory in high resistance amorphous reset state due to pressure-induced amorphization is occurred by application to PCM several short electrical (current or voltage) pulses. Such pulses are also referred to here as a “reset train”. The reset train applied to a PCM in set state heats up phase-change alloy (PCA) to a temperature lower than the melting point Tm. Nevertheless the PCM changes to the reset state due to the pressure on PCA because of mechanical stresses in the PCM device. This means that the reset current amplitude in the memory has decreased, therefore lowering power needed to program PCM.

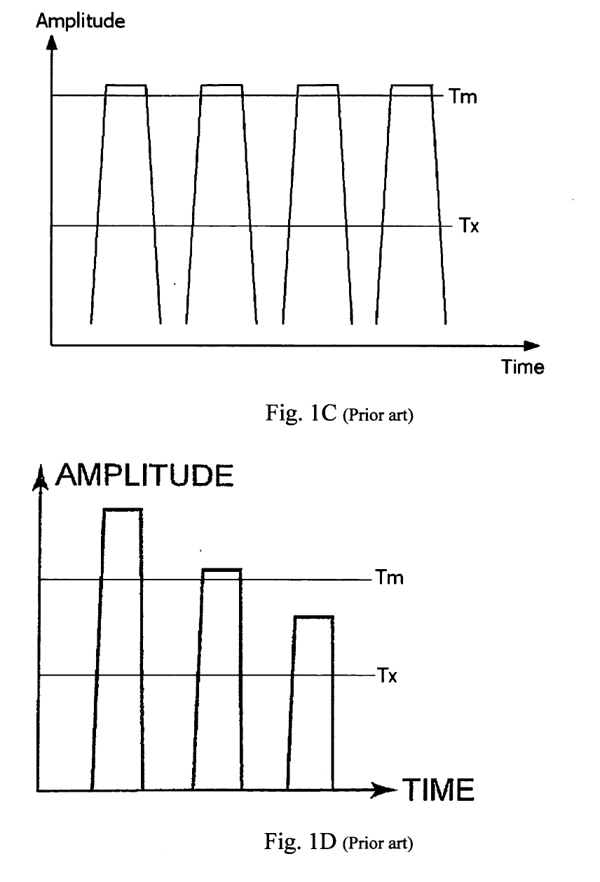

FIG. 2 illustrates a generic phase-change memory device 200, according to an embodiment of the invention. Two conductive electrodes 202 and 206 are in mechanical and electrical contacts with a phase-change alloy 204.

The first and second electrodes 202 and 206 can be made from a metal (e.g., Ti or Pt or Pt—Ir or Mo), conductive carbon or conductive composite (e.g., TaSiN or TiSiAl).

The electrodes 202 and 206 can consist of single layer or several layers of relatively conductive materials.

The coefficients of thermal expansion and the compressibilities of at least one of electrodes 202 and 206 are smaller than the coefficients of thermal expansion and the compressibility of the PCA 204 in PCM device 200. The hardness and elastic modulus of PCA 204 are smaller than hardnesses and elastic modules of at least one of electrodes 202 and 206 in PCM device 200.

The hardness of at least one of electrodes 202 or 206 is 101 percent or above of the hardness of PCA 204.

The thermal expansion coefficient of at least one of electrodes 202 or 206 is 99 percent or smaller than the thermal expansion coefficient of PCA 204.

The compressibility of at least one of electrodes 202 or 206 is 99 percent or smaller than the compressibility of PCA 204.

The phase change alloy (PCA) 204 consists of at least one pnictogen (for example, Sb or Bi or As) or at least one chalcogen (for example, Te or Se or S) and can contain one or more chemical elements (for example, H, F, In, Sn, Ge or Si) that form atomic bond with the pnictogen (or the chalcogen) with energy smaller than the energy of the bond between said pnictogen atoms (or said chalcogen atoms). The atomic structure of said phase-change material is easily deformed by external pressure due to significant concentration of vacancies (from 1% of atomic sites to 85% of atomic sites). Such PCA 204 examples are H—Sb—Te or F—Sb—Se—Te or Ge—Sb—Te or Bi—Sb—Te or In—Sb—Te or Sb—In—Ge—Te or Sn—H—Sb or Bi—F—Sb.

PCA 204 consists of a single phase-change alloy or multiple phase-change alloys mixed together or layered between the first electrode 202 and the second electrode 206.

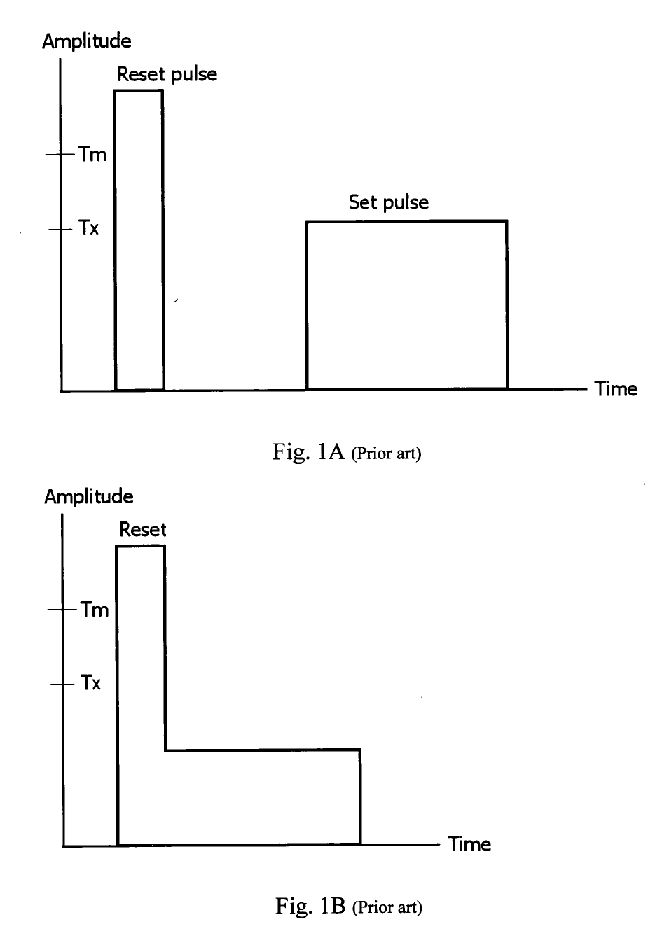

The programming of PCM device in the set state occurs by relatively long pulses (e.g., 200 ns) shown in FIG. 1A as it is known in the art.

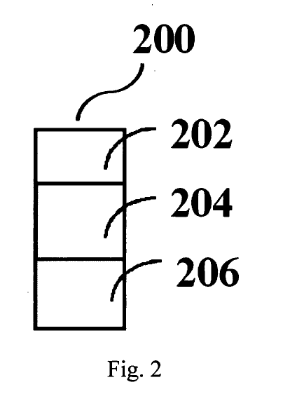

The programming of PCM device in the reset state occurs according to embodiments of this invention by the reset train of N short pulses (e.g., 10 ns) shown in FIG. 3 or FIG. 4 or FIG. 5. A reset train has number of pulses N between 2 and 1000. A duty cycle of these pulses is between 15% and 95%. A pulse in a reset train can be rectangular or triangle or trapezoidal or have another free shape with sharp leading and falling edges from 0.01 picoseconds to 200 nanoseconds and pulse duration from 1 picoseconds to 100 milliseconds.

The maximum current amplitude of each of these short pulses is not enough to melt PCA 204, although they heat up the PCA 204 below melting temperature Tm. The pulses of reset train heat up PCA 204 above crystallization temperature Tx in some embodiments.

FIGS. 3-5 show different reset trains. The amplitudes of reset and set signals are shown for the comparison.

FIG. 3A illustrates a sequence of rectangular programming pulses with the same amplitude and the same duration included in a reset train, according to some embodiments of the invention.

FIG. 3B illustrates a sequence of rectangular programming pulses with the same amplitude and different durations included in a reset train, according to some embodiments of the invention.

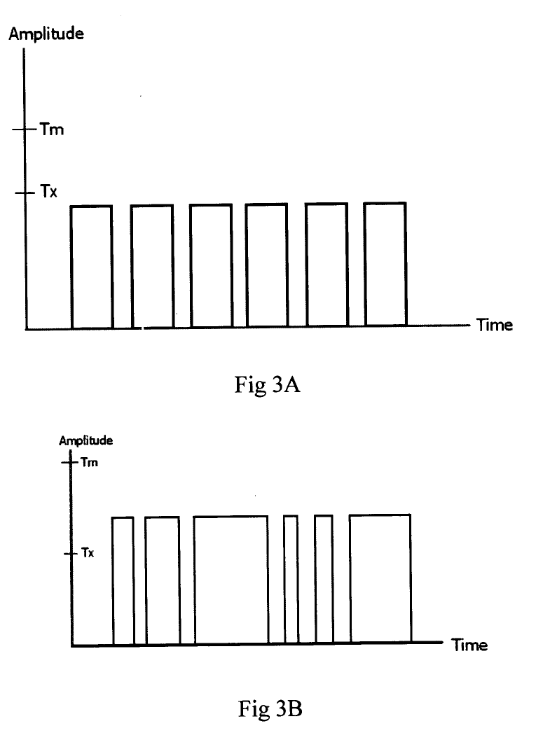

FIG. 4 illustrates a sequence of triangular programming pulses included in a reset train, according to an embodiment of the invention.

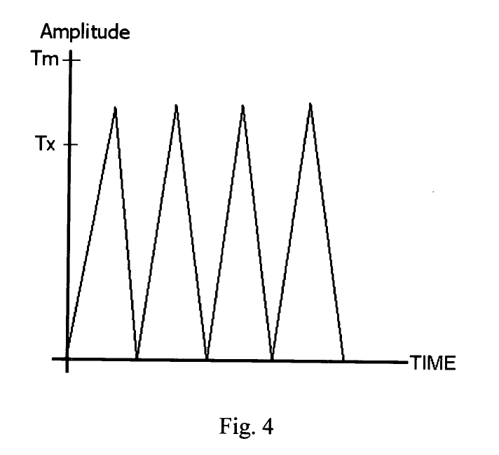

FIG. 5A illustrates a sequence of rectangular programming pulses with non-equal decreasing amplitudes included in a reset train, according to an embodiment of the invention. The highest amplitude pulse cannot melt PCA.

FIG. 5B illustrates a sequence of rectangular programming pulses with non-equal increasing amplitudes included in a reset train, according to an embodiment of the invention. The highest amplitude pulse cannot melt PCA.

In order to reduce number of pulses in a reset train the present and desired PCM 200 resistance can be compared between the pulses. The pulses in the train can be optimized (e.g., has a certain functional dependence of pulse shape and duty cycle) in order to achieve or to exceed the predetermined resistance of PCM 200 in shortest time with smallest energy consumption.

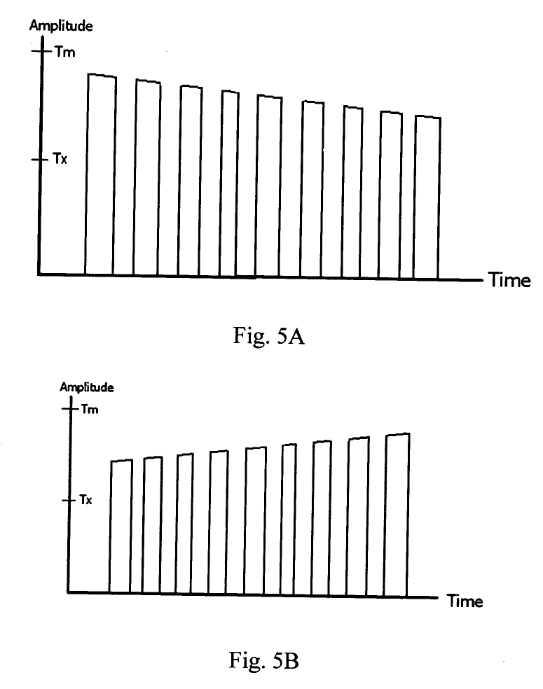

The reset train applied to set PCM device 200 leads to significant thermal expansion of the PCA 204 but relatively small thermal expansions of the electrodes 202 and 206. Mismatch of the thermal expansions creates strong pressure and mechanical stresses in the PCA 204 that lead to amorphization of the PCA 204. In result of the amorphization PCA 204 becomes high resistive and PCM device is converted into reset state. FIG. 6 shows an example of the reset state obtained by a reset train with equal amplitude and duration pulses shown in FIG. 3A. Any known in the art set pulse converts the PCA 204 back into crystalline low resistance state. Such cycle can be repeated many times and both set and reset states obtained by reset train and any known set pulse are non-volatile and can be used to store information in PCM device 200.

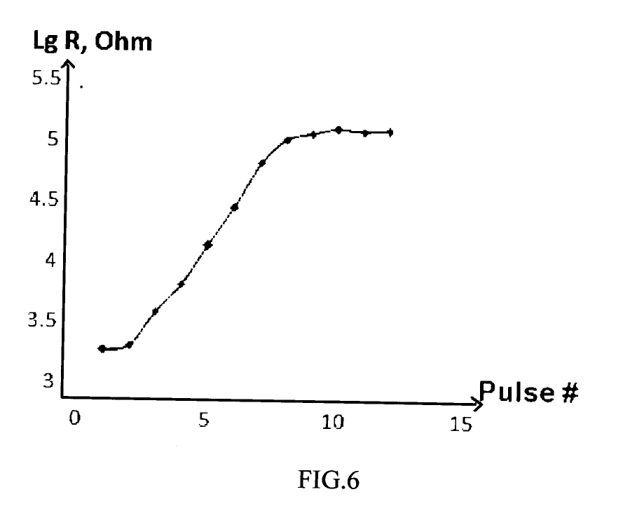

In order to increase efficiency of the reset train various embodiments of PCM device are proposed. A generic PCM device 700 is shown in FIG. 7. The PCM device 700 in an embodiment has two conductive electrodes 702 and 706, phase-change alloy 704, and casting 708 in mechanical contact with the PCA 704 in some embodiments.

The first and second electrodes 702 and 706 can be made from a metal (e.g., Ti or Pt or Pt—Ir or Mo), conductive carbon or conductive composite (e.g., TaSiN or TiSiAl) or another non-elastic conductive material with high hardness.

The phase change alloy (PCA) 704 consists of at least one pnictogen (for example, Sb) or at least one chalcogen (for example, Te) and can contain one or more chemical elements (for example, H, F, In, Sn, Bi) that form atomic bond with the pnictogen (or the chalcogen) with energy smaller than the energy of the bond between said pnictogen atoms (or said chalcogen atoms). The atomic structure of said phase-change material is easily deformed by external pressure due to significant concentration of vacancies (from 1% of atomic sites to 85% of atomic sites). Such PCA 704 examples are H—Sb—Te or F—Sb—Se—Te or Ge—Sb—Te or Bi—Sb—Te or In—Sb—Te or Sb—In—Ge—Te or Sn—H—Sb or Bi—F—Sb.

PCA 704 consists of a single phase-change alloy or multiple phase-change alloys mixed together or layered between the first electrode 702 and the second electrode 706 and surrounded by the casting 708.

The casting 708 can be made from electrical insulator such as SiO2 or Si3N4 or diamond-like carbon or other non-elastic nonconductive materials.

The casting 708 can be made from an electrostrictive material, such as lead magnesium niobate (PMN), lead magnesium niobate-lead titanate (PMN-PT) or lead lanthanum zirconate titanate (PLZT) in some embodiments.

PCA 704 consists of a single phase-change alloy or multiple phase-change alloys mixed together or layered between the first electrode 702 and the second electrode 706.

The electrodes 702 and 706 can consist of single layer or several layers of relatively conductive materials.

The coefficients of thermal expansion and the compressibilities of at least one of electrodes 702 and 706 are smaller than the coefficients of thermal expansion and the compressibility of the PCA 704 in PCM device 700. The hardness and elastic modulus of PCA 704 are smaller than hardnesses and elastic modules of at least one of electrodes 702 and 706 in PCM device 700.

The hardness of at least one of electrodes 702 or 706 is 101 percent or above of the hardness of PCA 704.

The thermal expansion coefficient of at least one of electrodes 702 or 706 and of casting 708 is 99 percent or smaller than the thermal expansion coefficient of PCA 704.

The compressibility of at least one of electrodes 702 or 706 is 99 percent or smaller than the compressibility of PCA 704.

The casting 708 has the same hardness as at least one of electrodes 702 or 706 hardness in one embodiment. The casting 708 has higher hardness than the electrodes 702 or 706 hardness in another embodiment. The casting 708 material has Brinell hardness above 600 in one embodiment.

The casting 708 has the same thermal expansion coefficient as the thermal expansion coefficient at least one of electrodes 702 or 706 in one embodiment. The casting 708 has smaller thermal expansion coefficient than the electrodes 702 or 706 thermal expansion coefficient in another embodiment.

The casting 708 has the same compressibility as at least one of electrodes 702 or 706 compressibility in one embodiment. The casting 708 has smaller compressibility than the electrodes 702 or 706 compressibility in another embodiment.

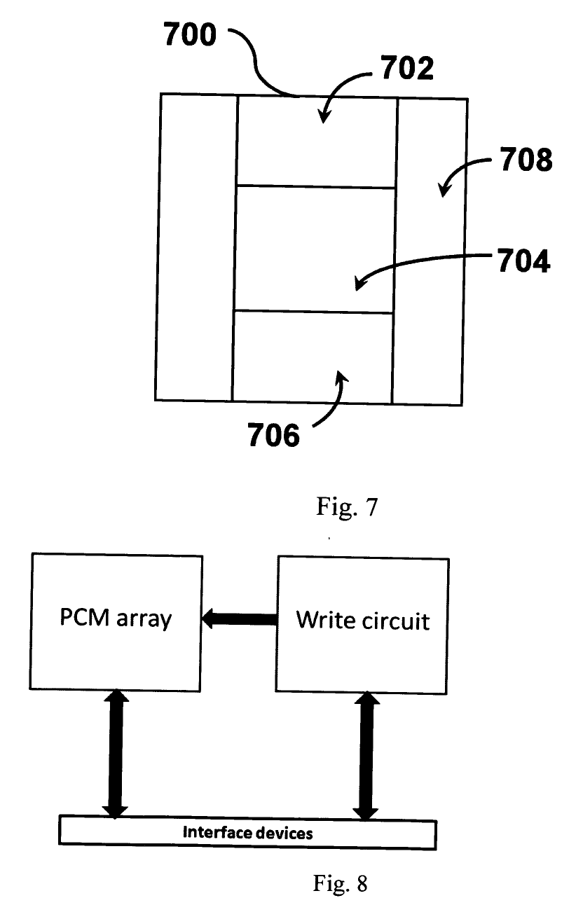

Memory array consists of plurality of PCM cells (e.g., shown in FIG. 2 or in FIG. 7) electrically connected with the write circuit as shown in FIG. 8. The write circuit provides set and reset pulses described in the previous sections. The memory array and the write circuit are coupled with an interface device, e.g. with computer or cellular phone. Anybody skilled in the art can easily choose or design the specially constructed or/and general-purpose write circuit and memory array.

A non-electrical signal such as optical or any combination of electrical and non-electrical signals produces the pressure-induced amorphization of phase-change alloy in some embodiments.

### LEGAL BOUNDARIES OF INVENTION

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of portions and/or steps and/or segments may be exaggerated for clarity.

It will be understood that, although the terms first, second, third etc. may be used herein to describe various portions and/or steps and/or segments, these portions and/or steps and/or segments should not be limited by these terms. These terms are only used to distinguish one portion and/or step and/or segment from another portion and/or step and/or segment. Thus, a first portion and/or step and/or segment discussed below could be termed a second portion and/or step and/or segment without departing from the teachings of the present invention.

Temporary relative terms, such as “after,” and “before” and the like, may be used herein for ease of description to describe one portions and/or steps and/or segments or feature's relationship to another portions and/or steps and/or segments(s) or feature(s) as illustrated in the figures.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated portions and/or steps and/or segments and/or features, but do not preclude the presence or addition of one or more other portions and/or steps and/or segments, and/or features thereof.

Example embodiments of the present invention are described herein with reference to drawings that are schematic illustrations of idealized embodiments of the present invention. As such, variations from the shapes of the illustrations as a result, for example, of a noise or a signal's attenuation in circuits and memory array, are to be expected. Thus, example embodiments of the present invention should not be construed as limited to the particular shapes of regions illustrated herein but are to include deviations in shapes that result, for example, from signals processing. Thus, the portions illustrated in the figures are schematic in nature and their shapes are not intended to illustrate the actual shape of a signal portion and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein in connection with the description of the invention, the term “about” means+/−10%. By way of example, the phrase “about 100” indicates a range of between 90 and 110. With the above embodiments in mind, it should be understood that the invention may employ various computer-implemented operations involving data stored in computer systems. These operations are those requiring physical manipulation of physical quantities. Usually, though not necessarily, these quantities take the form of electrical or magnetic signals capable of being stored, transferred, combined, compared, and otherwise manipulated. Further, the manipulations performed are often referred to in terms, such as producing, identifying, determining, or comparing.

Any of the operations described herein that form portions and/or steps and/or segments of the invention are useful operations. The invention also relates to a device or an apparatus for performing these operations. The apparatus may be specially constructed for the required purposes, or it may be a general-purpose apparatus. In particular, various general-purpose or apparatus may be used with computer programs written in accordance with the teachings herein, or it may be more convenient to construct a more specialized apparatus to perform the required operations.

It will be further appreciated that the instructions represented by the operations in the above figures are not required to be performed in the order illustrated, and that all the processing represented by the operations may not be necessary to practice the invention. Further, the processes described in any of the above figures can also be implemented in the specially constructed or/and general-purpose apparatus.

Although the foregoing invention has been described in some details for purposes of clarity of understanding, it will be apparent that certain changes and modifications may be practiced within the scope of the appended claims.

Accordingly, the present embodiments are to be considered as illustrative and not restrictive, and the invention is not to be limited to the details given herein, but may be modified within the scope and equivalents of the appended claims.

While the above description contains specificities, these should not be construed as limitations on the scope of any embodiment, but as exemplifications of the presently preferred embodiments thereof. Many other ramifications and variations are possible within the teachings of the various embodiments. Thus the scope of the invention should be determined by the appended claims and their legal equivalents, and not by the examples given.

### CONCLUSION

All previously know methods of PCM programming into reset state described in the prior art and shown in FIG. 1 required melting and fast cooling of an active volume of a phase-change alloy (PCA).

The main advantage of this invention is the low current during reset train which amplitude is comparable with the set current. According to some embodiments of this invention it is NOT required to melt PCA during reset programming (FIGS. 3-6).

To summarize, various embodiments of a phase-change memory programming technique, referred to as a reset train, various embodiments of a phase-change material, and various embodiments of a phase-change memory device have been described. In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

Although a preferred embodiment of the present invention has been described for illustrative purposes, those skilled in the art will appreciate that various modifications, additions and substitutions are possible, without departing from the scope and spirit of the invention as disclosed in the accompanying main claims.

The present invention may be embodied in other specific forms without departing from the spirit or essential attributes thereof and, accordingly, reference should be made to the appended claims and any of their permutation or any attempt to go into their details, rather than to the foregoing specification, as indicating the scope of the invention.

1. A method of operating a phase-change memory device programmable to a plurality of high resistance states by train of electrical signals applying to said memory device, wherein an amplitude of said electrical signal is not big enough to melt said phase-change alloy in said memory device

2. The method of claim 1, wherein said electrical programming of said memory device to said high resistance state occurs due to pressure-induced amorphization of said phase-change alloy.

3. The method of claim 1, wherein an amplitude of said electrical signal is big enough to bring said phase-change alloy in said memory device above crystallization temperature.

4. The method of claim 1, wherein said train has from 2 to 1000 pulses with duty cycle from 15% to 95% delivered from a voltage source or a current source or an another source of energy.

5. The method of claim 4, wherein said pulses have the same amplitude.

6. The method of claim 4, wherein said pulses have different amplitudes.

7. The method of claim 4, wherein said pulses have the same duration.

8. The method of claim 4, wherein said pulses have different durations.

9. The method of claim 4, wherein said pulses have constant duty cycle.

10. The method of claim 4, wherein said pulses have variable duty cycle.

11. The method of claim 4, wherein said pulses have duration from 1 picosecond to 100 milliseconds.

12. The method of claim 4, wherein said pulses have trailing and falling edges from 0.01 picoseconds to 200 nanoseconds.

13. The method of claim 1, wherein present and desired device states of said phase-change memory device are compared in order to reduce number of pulses in said train.

14. A memory storage and retrieval device, comprising: (a) an electrically conductive first electrode; (b) an electrically conductive second electrode; and (c) a phase-change material stack between said first and second electrodes, said phase-change material has variable electrical conductivity, said electrical conductivity can be changed upon application of an electrical signal between said first and second electrically conductive electrodes during programming of said device according to the claim 1.

15. The memory storage and retrieval device according to claim 14, wherein the thermal expansion coefficient of at least one of said electrodes is 99 percent or smaller than the thermal expansion coefficient of said phase-change material.

16. The memory storage and retrieval device according to claim 14, wherein the hardness of at least one of said electrodes is 101 percent or above of the hardness of said phase-change material.

17. The memory storage and retrieval device according to claim 14, wherein the compressibility of at least one of said electrodes is 99 percent or smaller than the compressibility of said phase-change material.

18. The memory storage and retrieval device according to claim 14 wherein atomic structure of said phase-change material is easily deformed by external pressure due to significant concentration of vacancies or weak atomic bonds.

19. A memory storage and retrieval device, comprising: (a) an electrically conductive first electrode; (b) an electrically conductive second electrode; and (c) a phase-change material with variable electrical conductivity stack between said first and second electrodes; (c) a casting material, and, said phase-change material has variable electrical conductivity, said electrical conductivity can be changed upon application of an electrical signal between said first and second electrically conductive electrodes during programming of said device according to the claim 1.

20. The memory storage and retrieval device according to claim 19, wherein said casting is made from electrostrictive material compromising lead magnesium niobate (PMN) or lead magnesium niobate-lead titanate (PMN-PT) or lead lanthanum zirconate titanate (PLZT).

21. The memory storage and retrieval device according to claim 19, wherein said casting is electrical insulator compromising SiO2 or Si3N4 or diamond-like carbon.

22. The memory storage and retrieval device according to claim 19, wherein thermal expansion coefficient of said casting material is lower than thermal expansion coefficient of at least one of other components of said device.

23. The memory storage and retrieval device according to claim 19, wherein compressibility of said casting material is lower than compressibility of at least one of other components of said device.

24. The memory storage and retrieval device according to claim 19, wherein hardness of said casting material is higher than hardness of at least one of other components of said device.

25. The memory storage and retrieval device according to claim 19, wherein Brinell hardness of said casting material is larger than 600.

26. The method of creation of said pressure-induced amorphization of phase-change alloy according to the claim 2 by non-electrical means such as optical or another signal or by any combination of electrical and non-electrical signals.

27. An apparatus comprising: a phase change memory; and a write circuit capable to delivery a reset pulses to a phase change memory; and an interface device coupled with at least one of other components of the said apparatus comprising the phase change memory or the write circuit.
